(19) United States
(12) Patent Application Publication
(10) Pub. No.: US 2024/0119333 A1
(43) Pub. Date: Apr. 11, 2024

(54) QUBIT DEVICE AND METHOD OF OPERATING A QUBIT DEVICE

(71) Applicant: Institute of Science and Technology Austria (IST Austria), Klosterneuburg (AT)

(72) Inventors: Georgios KATSAROS, Klosterneuburg (AT); Daniel JIROVEC, Klosterneuburg (AT)

(73) Assignee: Institute of Science and Technology Austria (IST Austria), Klosterneuburg (AT)

(21) Appl. No.: 18/038,244

(22) PCT Filed: Sep. 28, 2021
(86) PCT No.: PCT/EP2021/076627

§ 371 Date: May 23, 2023

(30) Foreign Application Priority Data
Nov. 25, 2020 (EP) 20386054.9

(51) Int. Cl. G06N 10/40; H01L 29/12; H01L 29/423; H01L 29/66

(52) U.S. Cl. CPC G06N 10/40; H01L 29/122; H01L 29/423; H01L 29/66977

(57) ABSTRACT

The disclosure relates to a qubit device and to methods of operating a qubit device. In one arrangement, a quantum well structure hosts a hole gas in a quantum well. Electrodes form a plurality of quantum dots in the hole gas and allow encoding of a unit of quantum information in hole spins in the quantum dots. X-rotations on the Bloch sphere can be implemented using a g-factor difference between hole spins and a low applied magnetic field. Z-rotations can be implemented using the exchange interaction.

The invention relates to a qubit device and to methods of operating a qubit device.

Quantum computers have various well-known advantages over classical computers, including the ability to solve certain classes of mathematical problem with higher efficiency. Quantum computers use quantum bits, commonly referred to as qubits, instead of the classical bits used in a classical computer. A qubit device is a device used to implement a qubit.

A promising approach for implementing a qubit is to encode information in the spin degrees of freedom of multiple electrons trapped in respective quantum dots. However, controlling such multi-electron spin encoding can be challenging, requiring complex high frequency signals and micromagnets. It has proven difficult to achieve practical scalability and high-fidelity fast readout.

It is an object of the present disclosure to provide an improved qubit device that at least partially addresses one or more of the issues described above.

According to an aspect of the invention, there is provided a qubit device, comprising: a quantum well structure configured to host a hole gas in a quantum well; and a plurality of electrodes configured to allow the formation of a plurality of quantum dots in the hole gas and to allow encoding of a unit of quantum information in a plurality of hole spins hosted in the quantum dots.

Thus, a qubit device is provided that is based on encoding a unit of quantum information in a plurality of hole spins rather than electron spins. The inventors have found that this alternative approach allows high manipulation speeds and low dephasing rates to be achieved. The use of holes provides strong spin orbit coupling (SOC), which leads to high manipulation speeds and, due to the low hyperfine interaction, low dephasing rates are expected. In some embodiments, the hole spins are holes in Ge. Holes in Ge have particularly strong spin orbit coupling (SOC). In addition, the SOC together with the low effective mass relax fabrication constraints, and larger quantum dots can be operated as qubits without the need for microstrips and micromagnets.

The inventors have further discovered that qubit devices based on hole spins, in accordance with the present disclosure, can be operated at very low magnetic fields. In particular, the qubit devices can be operated at magnetic fields that are below the critical field for a range of superconductors, including aluminium, which allows integration with circuits that use superconducting elements, such as Josephson parametric amplifiers, superconducting resonators and superconducting quantum interference devices. Such integration facilitates scalability and/or high-fidelity fast readout.

In some embodiments, the quantum well structure comprises a heterostructure of semiconductor layers. This approach allows efficient integration with existing semiconductor manufacturing technologies.

In some embodiments, the quantum information is encoded into singlet and triplet states of the hole spins hosted in the plurality of quantum dots, for example in a double quantum dot (DQD). The inventors have demonstrated particularly efficient operation in this regime, with a Ge hole spin qubit in a DQD device being shown to be operable at very low fields, including below the critical field of aluminium.

In some embodiments, the quantum well structure comprises a quantum well layer comprising more than 90% Ge, preferably isotopically purified Ge. The use of isotopically purified Ge reduces a magnetic noise contribution (due to reduced amounts of Ge isotopes having nuclear spin), allowing additional improvements in qubit coherence and quality.

In some embodiments, the device implements X-rotations on the Bloch sphere of the qubit using the g-factor difference between hole spins and an applied magnetic field, wherein the applied magnetic field is preferably below 100 mT (optionally significantly lower, such as below 10 mT). The inventors have found that extremely high X-rotation speeds and long dephasing times can be achieved in this manner, leading to high manipulation speeds and low dephasing rates. The low magnetic fields facilitate integration with superconducting devices, as mentioned above.

In some embodiments, the hole gas is a two-dimensional hole gas in a planar quantum well layer of a heterostructure of semiconductor layers. The plurality of quantum dots comprises a double quantum dot having a first quantum dot and a second quantum dot. The first quantum dot hosts a first hole participating in the encoding of the unit of quantum information (the first quantum dot may host other, lower energy holes that do not participate). The second quantum dot hosts a second hole participating in the encoding of the unit of quantum information (the second quantum dot may host other, lower energy holes that do not participate). The plurality of electrodes comprises a first set of electrodes configured to form the first quantum dot and a second set of electrodes configured to form the second quantum dot. The device localizes hole wavefunctions in the first and second quantum dots in regions having different compositions. It is expected that localizing the two holes in regions having different compositions will influence the g-factor difference. This approach therefore provides control of the g-factor difference and thereby facilitates configuration of the device for use at low fields.

In some embodiments, the first and second sets of electrodes are arranged asymmetrically relative to each other to promote the size, shape, orientation and/or hole occupancy of the first quantum dot being different from the size, shape, orientation and/or hole occupancy of the second quantum dot. This approach provides a flexible range of options for achieving high g-factor differences with high reliability and efficiency, thereby facilitating configuration of the device for use at low fields.

According to a further aspect of the invention, there is provided a method of operating a qubit device that uses the qubit device of any of the embodiments of the present disclosure. The method comprises using the plurality of electrodes to encode a unit of quantum information in a plurality of hole spins hosted in the quantum dots.

In some embodiments, the plurality of quantum dots comprises a double quantum dot having a first quantum dot hosting a first hole participating in the encoding of the unit of quantum information and a second quantum dot hosting a second hole participating in the encoding of the unit of quantum information. In such embodiments, the method may comprise controlling the electrodes such that the size, shape, orientation, hole occupancy in the first quantum dot, localization of the wavefunction of the first hole and/or electric field experienced by the first hole is/are respectively different from the size, shape, orientation, hole occupancy in the second quantum dot, localization of the wavefunction of the second hole and/or electric field experienced by the second hole. The control may comprise tuning a g-factor difference by adjusting at least one of the following: a difference in size of the first quantum dot relative to the second quantum dot; a difference in shape of the first quantum dot relative to the second quantum dot; a difference in orientation of a shape of the first quantum dot relative to the second quantum dot; a difference in hole occupancy in the first quantum dot compared to the second quantum dot; a difference in composition at a location of the centre of mass of the wavefunction of the first hole compared to the second hole; and a difference in electric field experienced by the first hole compared to the second hole. The tuning of the g-factor difference may comprise tuning the g-factor difference to be at least 1, preferably at least 2, preferably at least 3, preferably 4 or more.

Thus, a methodology is provided in which various parameters (“knobs”) may be used to flexibly and efficiently control (e.g. achieve a high) a g-factor difference between hole spins in different quantum dots of a double quantum dot. This approach facilitates operation of a qubit device at low magnetic fields.

The invention will now be further described, by way of example, with reference to the accompanying drawings, which are summarised below.

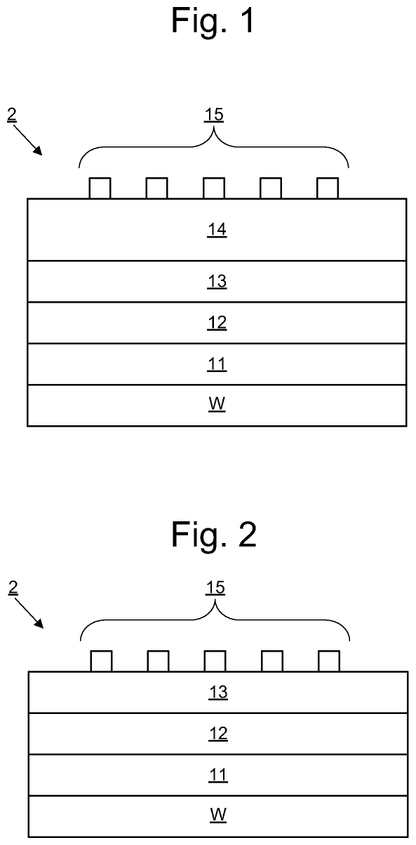

FIG. 1 is a schematic cross-sectional view of a qubit device according to an embodiment.

FIG. 2 is a schematic cross-sectional view of a qubit device according to an alternative embodiment.

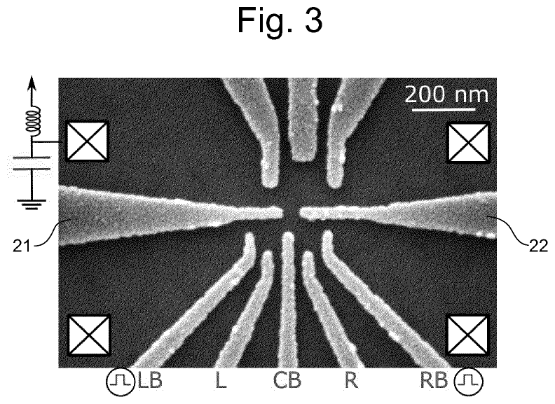

FIG. 3 is a scanning electron microscope (SEM) image of a gate layout used for implementing a control arrangement for the device of FIG. 1 or 2.

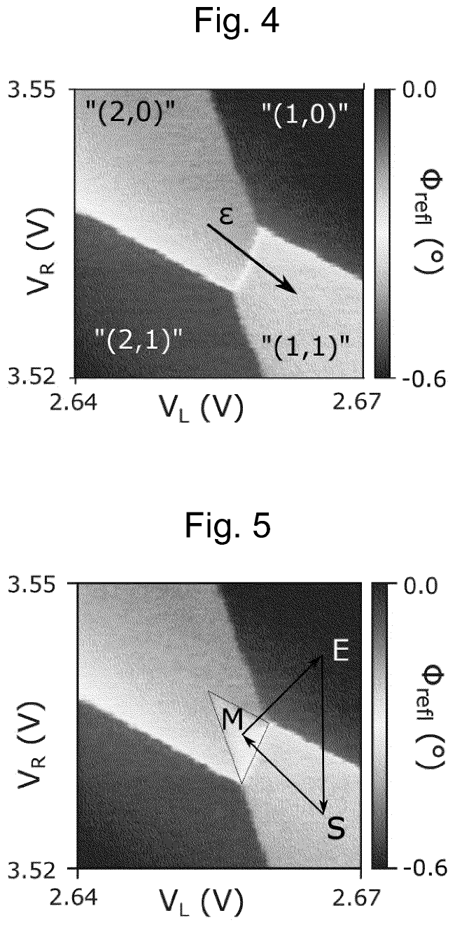

FIG. 4 depicts a stability diagram for the parameter region of interest. The effective number of holes in each Coulomb blocked island is defined as “(N_{L}, N_{R})”. The quotes symbolize an equivalent hole number. The quotes are omitted in the description below. The diagonal arrow corresponds to a detuning (ϵ) axis.

FIG. 5 depicts a stability diagram acquired while pulsing in a clockwise manner following the arrows. The system is emptied (E) in (1,0) and pulsed to (1,1) (separation point S) where either a singlet or a triplet will be loaded. Upon pulsing to the measurement point (M) in (2,0), triplet states are blocked leading to the marked triangular blockade region.

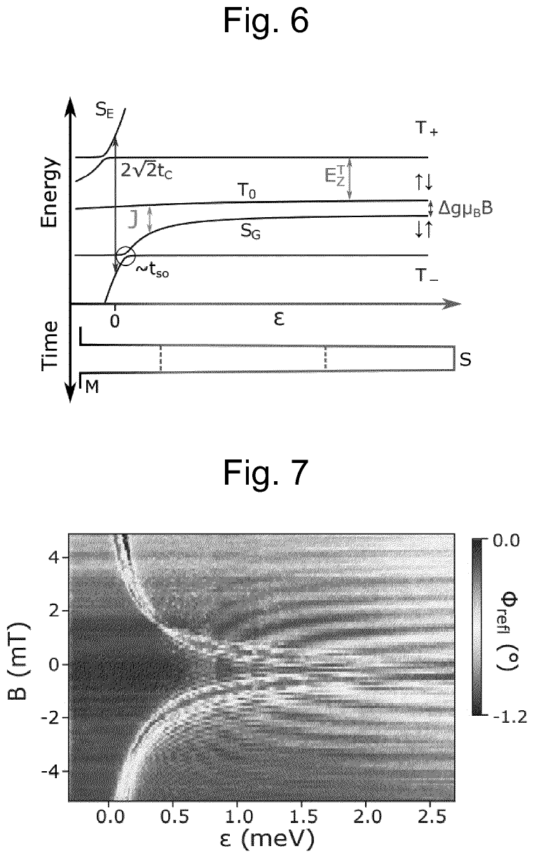

FIG. 6 (upper graph) depicts an energy dispersion relation as a function of ϵ at finite magnetic field. ϵ=0 is defined at the (2, 0)⇄(1, 1) resonance. At high ϵ the Hamiltonian has the four eigenstates: two polarized triplets |T₋ [symbol] =|↓↓ [symbol] , |T₊ [symbol] =|↑↑ [symbol] and two anti-parallel spin states |↑↓ [symbol] , |↓↑ [symbol] . The triplet Zeeman energy E_{Z}^{T}=±Σgμ_{B}B/2 lifts the degeneracy of the triplets. The singlet energy

$${E}_{S} = \frac{ϵ}{2} - \sqrt{\frac{{ϵ}^{2}}{4} + 2 {t}_{C}^{2}} ,$$

where t_{C} is the tunnel coupling between the dots, anti-crosses with the polarized triplet states due to spin-orbit interaction parametrized by t_{SO}. The singlet S_{G}:=S and triplet T₀ are split in energy by the exchange interaction J which decreases with increasing ϵ.

FIG. 6 (lower graph) depicts a pulse sequence used to acquire the spin funnel shown in FIG. 7. Starting from (2,0) the system is pulsed to (1,1) at varying ϵ, left evolving for 100 ns and then pulsed back to measure in M.

FIG. 7 depicts the results of a spin funnel experiment confirming the energy dispersion shown in FIG. 6 (upper graph) and the validity of assuming an effective hole number of (2,0) and (1,1). When J(ϵ)=E_{Z}^{T} the triplet signal increases as a result of S−T₋ intermixing. Around the funnel S−T₋ oscillations can be observed while at higher detuning S=T₀ oscillations become more prominent.

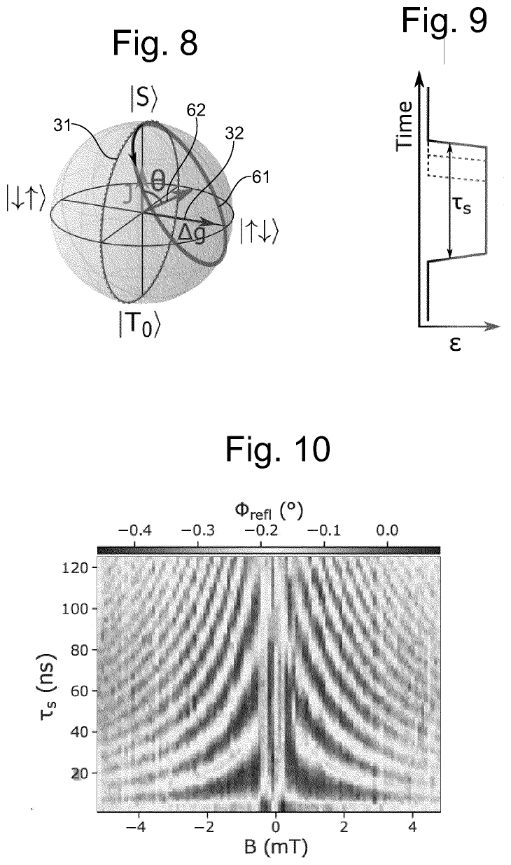

FIG. 8 depicts state evolution on the Bloch sphere, with trajectories shown that correspond to a perfect X-rotation and to an effective rotation tilted by an angle θ from the Z-axis.

FIG. 9 depicts example pulse sequences for performing X-rotations.

FIG. 10 is a graph depicting observed X-oscillations as a function of τ_{S} and B at V_{CB}=910 mV.

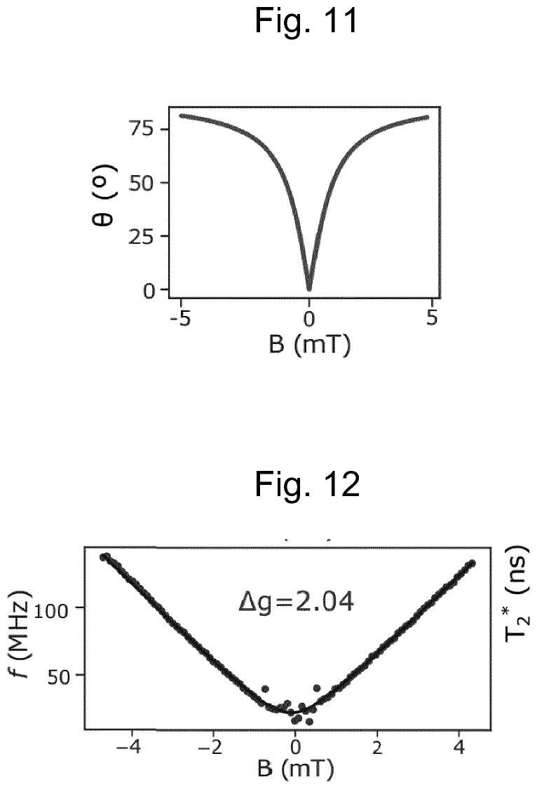

FIG. 11 is a graph depicting variation of the angle θ as a function of B.

FIG. 12 is a graph depicting variation of a frequency ƒ of the X-oscillations as a function of B.

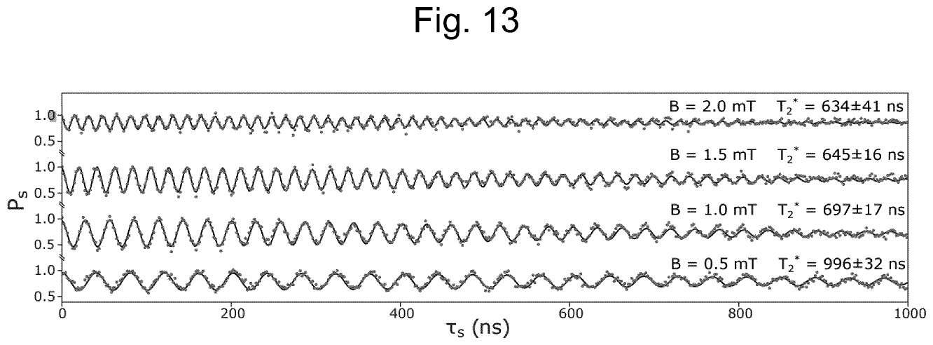

FIG. 13 is a graph depicting singlet probabilities P_{S} as a function of τ_{S} for different magnetic fields.

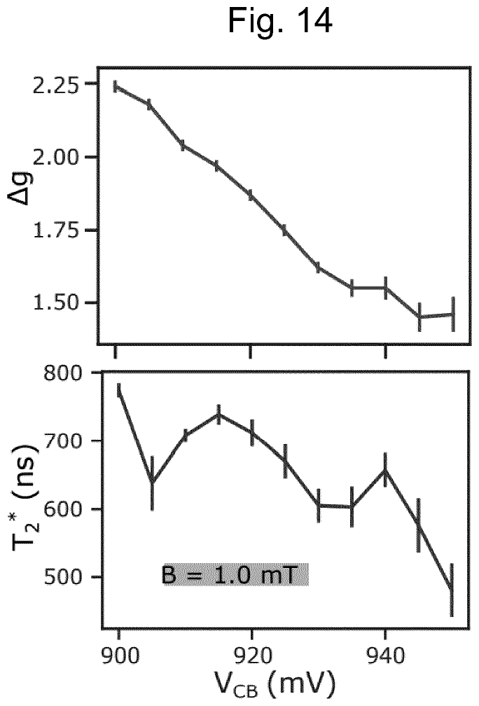

FIG. 14 (upper graph) is a graph depicting the g-factor difference Δg as a function of V_{CB}.

FIG. 14 (lower graph) is a graph depicting the variation of the inhomogeneous dephasing time T*₂ as a function of V_{CB}.

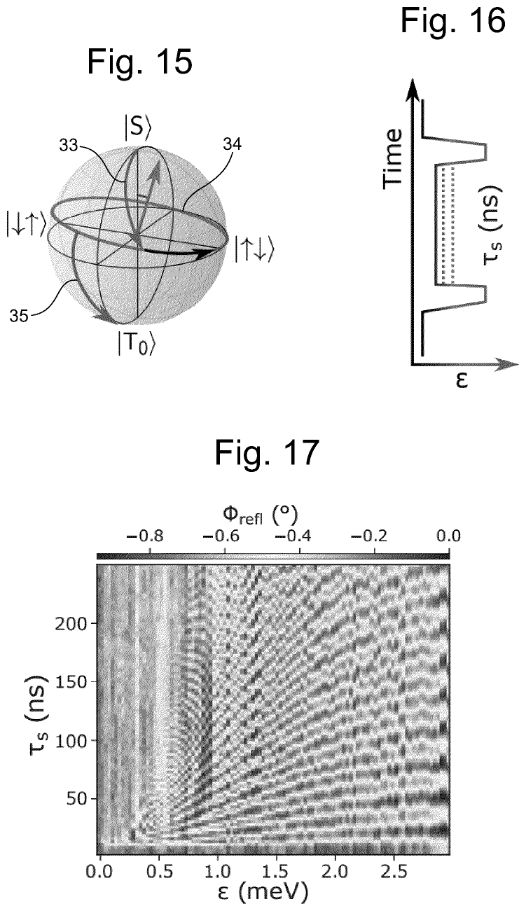

FIG. 15 depicts the state evolution on the Bloch sphere, with trajectories showing application of

$$\frac{{π}_{x}}{2} - pulses$$

applied at maximum detuning and subsequent free evolution at smaller ϵ.

FIG. 16 depicts example pulse sequences for probing Z-rotations.

FIG. 17 is a graph depicting observed Z-oscillations as a function of τ_{S} and ϵ.

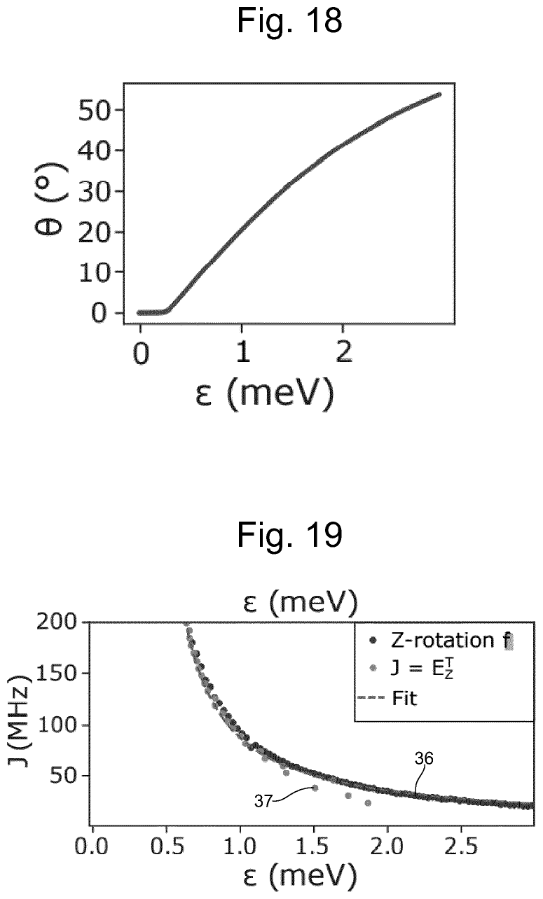

FIG. 18 is a graph depicting variation of θ as a function of ϵ.

FIG. 19 is a graph depicting variation of J as a function of ϵ.

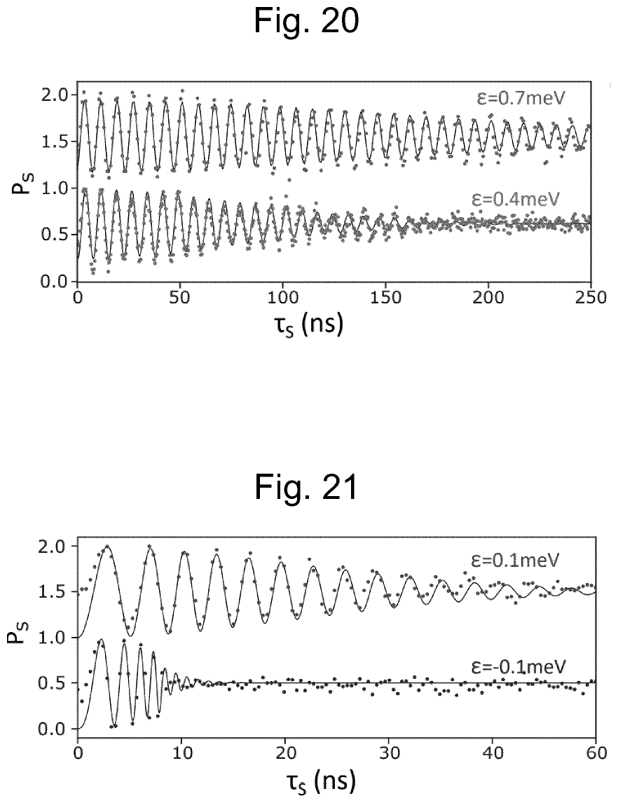

FIGS. 20 and 21 are the graphs depicting variation of P_{S} as a function of τ_{S} and ϵ.

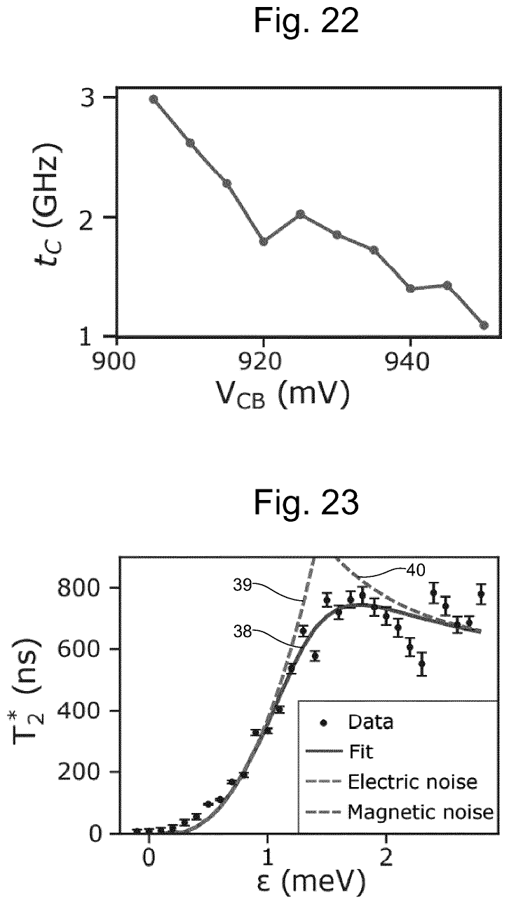

FIG. 22 is a graph depicting tunnel coupling t_{C} as a function of V_{CB} demonstrating good control over the tunnel barrier between the two quantum dots.

FIG. 23 is a graph depicting variation of T*₂ as a function of ϵ.

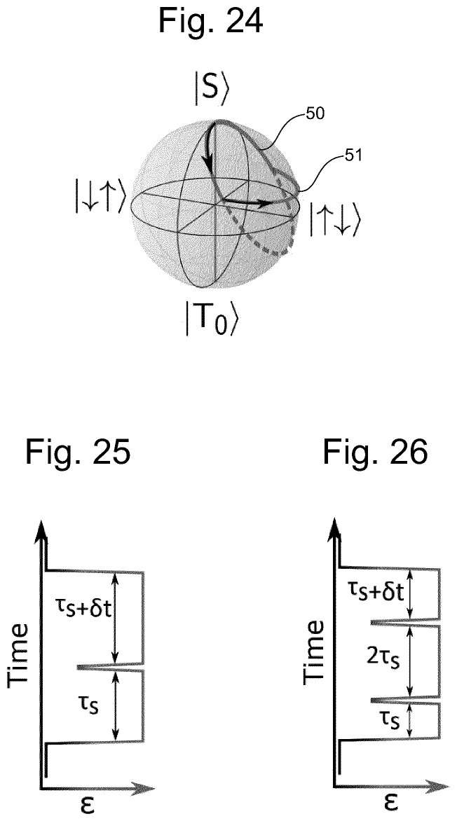

FIG. 24 depicts the state evolution on the Bloch sphere, with trajectories showing application of short exchange pulses to implement spin echo technique.

FIGS. 25 and 26 depict example pulse sequences for one and two refocusing pulses.

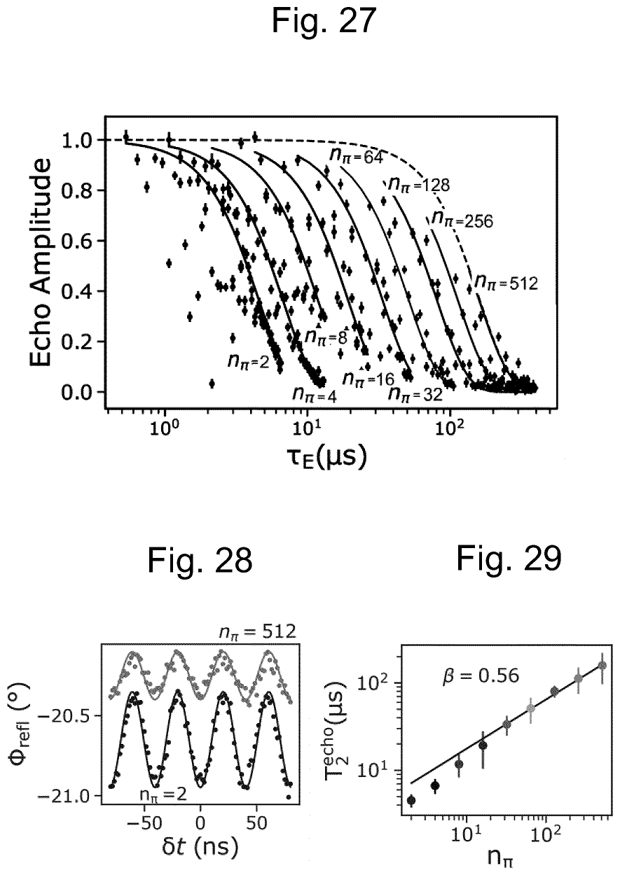

FIG. 27 is a graph depicting the normalized echo amplitude as a function of total separation time for different numbers of π-pulses.

FIG. 28 is a graph depicting examples of S−T₀ oscillations as a function of δt taken for the points highlighted by arrows in FIG. 27.

FIG. 29 is a graph showing the power law dependence of T₂^{Echo} vs n_{π}.

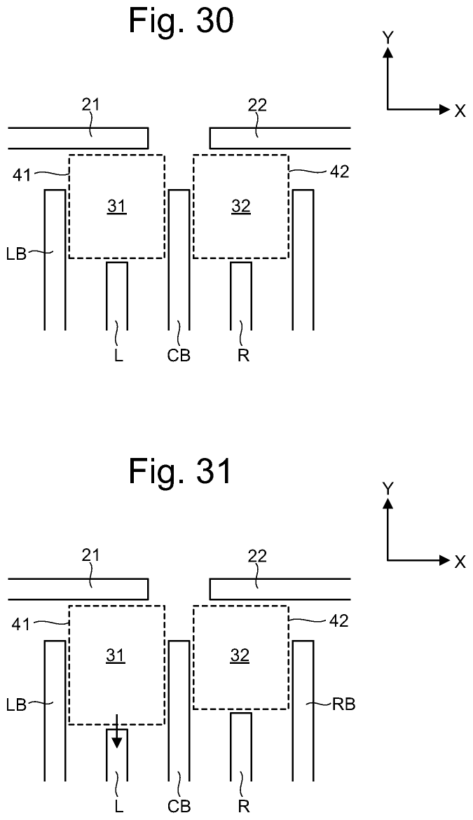

FIG. 30 is a schematic top view of first and second sets of electrodes for forming a double quantum dot.

FIGS. 31-34 show example position adjustments of the electrodes of FIGS. 30 to provide a large g-factor difference.

FIG. 35 is a schematic top view of an alternative configuration of first and second sets of electrodes comprising depth control electrodes.

The present disclosure relates to qubit devices. Qubit devices are devices for implementing a quantum bit (commonly referred to as a qubit). In some embodiments, a qubit device comprises a quantum well structure 2 and a plurality of electrodes 15, as exemplified in FIGS. 1 and 2. The quantum well structure 2 is configured to host a hole gas. In some embodiments, as exemplified in detail below, the hole gas is a two-dimensional hole gas. However, the hole gas could alternatively be a one-dimensional hole gas. The electrodes 15 are configured to allow the formation of a plurality of quantum dots in the hole gas. The electrodes 15 are further configured to allow encoding of a unit of quantum information in a plurality of hole spins in the quantum dots. In some embodiments, the unit of quantum information is encoded into singlet and triplet states of the hole spins hosted in the quantum dots. As exemplified in detail below, the plurality of quantum dots in which the unit of quantum information is encoded may consist of a double quantum dot (i.e. two quantum dots).

The quantum well structure 2 may comprise a quantum well formed within a heterostructure of semiconductor layers. The heterostructure of semiconductor layers may be provided on a substrate W, such as a silicon wafer. In some embodiments, the quantum well structure 2 comprises a quantum well layer 12 sandwiched between two confinement layers. The quantum well layer 12 may comprise a semiconductor with a relatively small bandgap (commonly referred to as a quantum well) and the confinement layers may comprise semiconductors with larger bandgaps. In the examples shown, the two confinement layers comprise a lower confinement layer 11 and an upper confinement layer 13.

The quantum well layer 12 may comprise more than 90% Ge, preferably more than 95% Ge, preferably more than 96% Ge, preferably more than 97% Ge, preferably more than 98% Ge, preferably more than 99% Ge. Preferably, the Ge in the quantum well layer 12 comprises, consists essentially of, or consists of isotopically purified Ge (with reduced amounts of Ge isotope having nuclear spin relative to naturally occurring Ge). Alternatively, the Ge in the quantum well layer 12 may comprise, consist essentially of, or consist of, naturally occurring Ge. The thickness of the quantum well layer 12 may be in the range of 1-50 nm, preferably 5-25 nm, preferably 10-20 nm.

Either or both of the confinement layers 11 and 13 may comprise, consist essentially of, or consist of, SiGe with a Si content in the range of 5-50% and a Ge content in the range of 95-50%. Preferably, the Si content is in the range of 5-40%, even more preferably in the range of 20-40%. In embodiments of this type, the quantum well structure 2 may comprise an oxide support layer 14 for supporting the electrodes 15, as exemplified in FIG. 1. Either or both of the confinement layers 11 and 13 may have a thickness in the range of 10-200 nm, preferably 10-100 nm, preferably 20-60 nm.

In an alternative approach, as exemplified in FIG. 2, the quantum well structure 2 may be formed using Ge on insulator technology. In an embodiment of this type, either or both of the confinement layers may comprise an oxide layer. For example, the lower confinement layer 11 may comprise SiO₂ and the upper confinement layer 13 may comprise any oxide suitable for supporting the electrodes 15. The upper confinement layer 13 of the embodiment of FIG. 2 might be the same oxide layer as oxide support layer 14 of the embodiment of FIG. 1. The upper confinement layer 13 of FIG. 2 and/or the oxide support layer 14 of FIG. 1 preferably has a thickness in the range of 5-50 nm, preferably 5-35 nm. The upper confinement layer 13 of FIG. 2 and/or the oxide support layer 14 of FIG. 1 may comprise, consist essentially of, or consist of, one or more of the following, optionally formed by atomic layer deposition: aluminium oxide, hafnium oxide, zirconium oxide (or any other high dielectric constant oxide). The layer may be grown for example at a temperature between 50-500 C using atomic layer deposition.

The electrodes 15 may comprise a plurality of gates. The electrodes 15 may be metallic. The gates may be configured to operate in a depletion mode, in which case they may be referred to as depletion gates. Alternatively, the gates may be configured to operate in an accumulation mode, in which case they may be referred to as accumulation gates. The electrodes may all be provided in the same layer, as exemplified in FIG. 1 or 2. Alternatively, electrodes may be provided in plural different layers separated from each other by an insulating layer, such as an oxide layer. Providing electrodes in different, electrically isolated layers may be particularly desirable for smaller geometries because it eases manufacturing tolerances. Electrodes in different layers can overlap with each other when viewed perpendicularly to the plane of the layered structure while still being electrically isolated from each other. An example arrangement for the electrodes 15 (gates) is described below with reference to FIG. 3. A first quantum dot is formed between gates LB and CB and a second quantum dot is formed between gates CB and RB. The lower gates (LB, L, CB, R, RB) thus form a double quantum dot (DQD) system. The upper gates tune a charge sensor (CS) dot. The separation gates in the middle are tuned to maximize the CS sensitivity to charge transitions in the DQD. An LC-circuit connected to a CS ohmic contact allows fast read-out through microwave reflectometry. LB and RB are further connected to fast gate lines enabling fast control of the energy levels in the DQD.

Thus, a quantum well is used to form the qubit by using gate electrodes to create quantum dots in the quantum well. Holes are localized in these quantum dots. The spin of the localized holes is used to encode the quantum information of the qubit. To operate the qubit, it is necessary to send appropriate electrical signals to the gate electrodes and to use a magnetic field.

The qubit can be read out (i.e. the unit of quantum information encoded in the hole spins of the double quantum dot can be read out, in the example shown) in various ways. In the example described below, the qubit is read out via charge sensing using a nearby quantum dot (the upper three terminals in FIG. 3). Alternatively, a quantum point contact could be used for the charge sensing. Alternatively, the qubit can be read out by dispersive read out (reflectometry with lumped elements or using a superconducting resonator). The read out may use the Pauli-spin blockade (PSB) phenomenon, which effectively provides a type of spin to charge conversion that allows the spin state of the qubit to be probed.

The qubit may be operated by performing rotations about two axes on the Bloch sphere of the qubit. This allows access to any point on the Bloch sphere, which is useful for quantum computation. In embodiments of the present disclosure, X and Z rotations are implemented. The X and Z rotations allow access to the full Bloch sphere.

In some embodiments, the device is configured to implement X-rotations on the Bloch sphere of the qubit using a g-factor difference between the hole spins in the quantum dots (e.g. in a double quantum dot) upon application of a small magnetic field. In some embodiments, the qubit is initialized in one state (e.g. a singlet state) and an electrical pulse is applied using the electrodes. The consequence of this electrical pulse is that the state is not any more an eigenstate (if the hole g-factors in the quantum dots are different). As a consequence, oscillations occur, which if the exchange interaction is sufficiently low can be about the X axis (or an axis near to the X-axis. The X-rotations correspond to oscillations between the singlet and triplet T₀ states. The magnetic field may be below 100 mT, preferably below 50 mT, preferably below 25 mT, preferably below 10 mT (as achieved in the examples discussed below). The device may thus be configured to apply electrical signals to the electrodes 15 and to apply a magnetic field to the quantum well structure 2. The device may thus comprise any suitable electrical equipment for providing these functionalities (e.g. power sources, circuit equipment, magnets, etc.). In some embodiments, the magnetic field is provided using a superconducting magnet or a permanent magnet. Alternatively, the magnetic field can be created with a ferromagnetic insulator (such as EuS) or a micromagnet made out of Ni, Co or Fe for example. The magnetic field can point at any orientation. The X-rotation frequency can be electrically tuned by making use of the tunability of hole g-factors.

In some embodiments, electrodes for forming quantum dots are configured and/or operated in such a way as to provide enhanced g-factor differences, thereby facilitating use at low magnetic fields. FIGS. 31-35 show example electrode configurations for achieving such functionality, viewed perpendicularly to the plane of the quantum well layer 12 of a quantum well structure 2 (e.g., as depicted in FIG. 1 or 2).

Embodiments of the type depicted in FIGS. 30-35 are applicable particularly to arrangements in which the hole gas is a two-dimensional hole gas in a planar quantum well layer 12 of a heterostructure of semiconductor layers, and the qubit device comprises a double quantum dot having a first quantum dot and a second quantum dot. The first quantum dot hosts a first hole participating in the encoding of the unit of quantum information. The second quantum dot hosts a second hole participating in the encoding of the unit of quantum information. Electrodes used to form the double quantum dot comprise a first set of electrodes (labelled LB, L, CB and 21 in FIGS. 30-34 and LB, L, CB, 21 and 23 in FIG. 35) and a second set of electrodes (labelled RB, R, CB and 22 in FIGS. 30-34 and RB, R, CB, 22 and 24 in FIG. 35). The first set of electrodes forms the first quantum dot generally in region 31. The second set of electrodes forms the second quantum dot generally in region 32. The first and second sets of electrodes may or may not share one or more electrodes. FIGS. 30-35 depict example configurations nominally of the type depicted in FIG. 3 and discussed above. Corresponding features are given the same reference numbers.

In some embodiments, the first and second sets of electrodes are arranged asymmetrically relative to each other to promote the size, shape, orientation and/or hole occupancy of the first quantum dot being different from the size, shape, orientation and/or hole occupancy of the second quantum dot. Thus, the electrodes may be configured to favor large g-factor differences by making the first and second quantum dots different sizes, different shapes, different orientations or a combination of different sizes, different shapes and/or different orientations. The difference or differences is/are understood to be larger than “de minimis”, i.e. significantly larger than differences that would arise merely from typical manufacturing tolerances. The differences may arise, for example, from differences in positions of respective electrodes in the first and second sets of more than 5 nm, preferably more than 10 nm, preferably more than 15 nm. The electrodes may additionally or alternatively be controlled such that a hole occupancy of (i.e. the number of holes in) the first quantum dot is different from a hole occupancy of the second quantum dot. Hole occupancy is affected by the electrode configuration but also by the voltages applied to the electrodes. For example, if the electrodes define a larger containment region for a given quantum dot it will typically be the case that higher voltages will be necessary to reduce the hole occupancy than if the containment region were smaller. Arranging for the hole occupancies to be different may lead to g-factor differences of the holes that participate in the encoding of information. These differences may promote operation of the qubit at very low fields. For example, in some embodiments the quantum well layer 12 has a composition that varies as a function of position and the wavefunctions of the first and second holes sample the varying composition differently. The wavefunctions of the first and second holes may sample different average compositions in the quantum well layer 12. In some embodiments, the electrodes are controlled such that the hole occupancy in the first quantum dot is at least 4 holes, preferably at least 6 holes, preferably at least 8 holes, different than the hole occupancy in the second quantum dot. The hole occupancies of each quantum dot in the double quantum dot can typically be made to take any odd integer value between 1 and about 11.

The electrodes may additionally or alternatively be controlled to achieve a high g-factor difference by arranging for the first and second holes to experience different electric fields (e.g. electric fields of different average magnitude, spatial distribution and/or direction). As described below, in some embodiments either or both of the first and second sets of electrodes comprises a depth control electrode 23, 24 that controls localization of hole wavefunctions in a depth direction of the quantum well layer 12. Such depth control electrodes can be used to change the electric field experienced by hole wavefunctions in different quantum dots. For example, in the case of a quantum well layer 12 of uniform composition (e.g. uniform Ge composition), applying different voltages to the depth control electrodes will lead to correspondingly different electric fields being experienced by the respective hole wavefunctions.

In some embodiments, the asymmetric arrangement is such that a maximum area of the first quantum dot viewed perpendicularly to the plane of the quantum well layer is at least 120%, preferably at least 140%, preferably at least 160%, preferably at least 200%, preferably at least 400%, preferably at least 800%, preferably at least 1200%, of a maximum area of the second quantum dot viewed perpendicularly to the plane of the quantum well layer. It is expected that useful performance will typically be achieved up to about a factor of 16 difference in maximum area, corresponding to a difference between quantum dot dimensions of about 50×50 nm and 200×200 nm. The sizes of the quantum dots can be influenced by the geometries of the electrodes and by the voltages applied to the electrodes. In some embodiments, the geometries of the electrodes are configured to favor different sized quantum dots.

For example, dimensions of the first quantum dot along orthogonal X- and Y-axes in the plane of the quantum well layer 12 may be respectively defined by an X-axis pair of electrodes of the first set and a Y-axis pair of electrodes of the first set. Similarly, dimensions of the second quantum dot may be defined by an X-axis pair of electrodes of the second set and a Y-axis pair of electrodes of the second set. In the examples of FIGS. 30-35, electrodes LB and CB are examples of an X-axis pair of the first set, electrodes CB and RB are examples of an X-axis pair of the second set, electrodes L and 21 are examples of a Y-axis pair of the first set, and electrodes R and 22 are examples of a Y-axis pair of the second set.

A first containment region 41 (schematically indicated by a broken line box) may be defined as the largest rectangular region between the X-axis and Y-axis pairs of electrodes of the first set. Similarly, a second containment region 42 may be defined as the largest rectangular region between the X-axis and Y-axis pairs of the second set. In the present disclosure it is to be understood that a square is a special form of rectangle, such that square falls within the scope of “rectangular”. A degree to which the electrodes promote different sizes of quantum dots can be quantified by referring to a difference between the sizes of the first and second containment regions 41, 42. For example, in correspondence with the above-described differences in quantum dot sizes, the electrodes may be configured such that the first containment region 41 is at least 120%, preferably at least 140%, preferably at least 160%, preferably at least 200%, preferably at least 400%, preferably above 800%, preferably above 1200%, of a maximum area of the second quantum dot viewed perpendicularly to the plane of the quantum well layer. It is expected that useful performance will typically be achieved up to about a factor of 16 difference in maximum area, corresponding to a difference between quantum dot dimensions of about 50×50 nm and 200×200 nm. as large as the second containment region 42. The first and second containment regions 41, 42 will typically each have dimensions in the X and Y directions in the range of 50-200 nm to form quantum dots efficiently. It will generally be desirable for asymmetries between the electrodes of the first and second sets to work within these limits (i.e. such that the dimensions in the X and Y directions do not fall outside of the range). For example, sizes of the first and second containment regions 41, 42 will typically remain in the range of 50×50 nm and 200×200 nm.

In some embodiments, the asymmetric arrangement of electrodes is such that the first quantum dot has a different shape to the second quantum dot when viewed perpendicularly to the plane of the quantum well layer 12. The different shape may comprise a different aspect ratio. The first and second containment regions 41, 42 may thus have different aspect ratios. The first quantum dot may be made more or less elongate than the second quantum dot. In some embodiments, the asymmetric arrangement is such that the first and second quantum dots have shapes that are each defined by a respective long axis and short axis when viewed perpendicularly to the plane of the quantum well layer. The shapes may be ellipses for example. This would typically correspond to the first and second containment regions 41, 42 being non-square rectangles. In some embodiments, the long axes are non-parallel to each other, for example perpendicular to each other. The inventors have found that such oppositely oriented elliptical dots provide large in-plane g-factor differences. In some embodiments, one of the shapes of the quantum wells is circular and the other is a (non-circular) ellipse. This would correspond to one of the containment regions being square and the other non-square. Example dimensions for any of the non-square containment regions mentioned above may include approximately 50×150 nm, 75×150 nm, and/or 75×125 nm.

In some embodiments, as exemplified in FIGS. 30-35, the X-axis pair of the first set and the X-axis pair of the second set together comprise three electrodes LB, CB and RB extending parallel to the Y-axis. The three electrodes comprise an outer electrode LB of the first set, an outer electrode RB of the second set, and an intermediate electrode CB between the outer electrodes LB, RB and shared between the two sets. The Y-axis pair of the first set comprises an electrode L extending parallel to the Y-axis and positioned between the outer electrode LB of the first set and the shared intermediate electrode CB, and a cross electrode 21 extending parallel to the X-axis. Similarly, the Y-axis pair of the second set comprises an electrode R extending parallel to the Y-axis and positioned between the outer electrode RB of the second set and the shared intermediate electrode CB, and a cross electrode 22 extending parallel to the X-axis. In the example shown the cross electrode 21 is electrically isolated from the cross electrode 22 but this is not essential; in other embodiments the cross electrodes 21 and 22 may be provided by a single continuous electrode, optionally also extending parallel to the X-axis. The single continuous electrode may for example be formed by providing conductive portions corresponding to the cross electrodes 21 and 22 but without any gap between them.

FIGS. 31-34 depict specific examples of asymmetric electrode configurations. FIG. 30 depicts a reference case where the electrodes are provided symmetrically.

In the arrangement of FIG. 30, the X-axis and Y-axis pairs are geometrically the same for the first and second sets. If the voltages were applied symmetrically, the first and second quantum dots could in theory be formed symmetrically (i.e., with the same size, shape and orientation).

FIG. 31 depicts an example where a separation between electrodes L and 21 of the Y-axis pair of the first set is increased by moving the electrode L downwards (in the figure) to provide an asymmetric electrode arrangement. The asymmetric arrangement results in the first containment region 41 being larger than the second containment region 42.

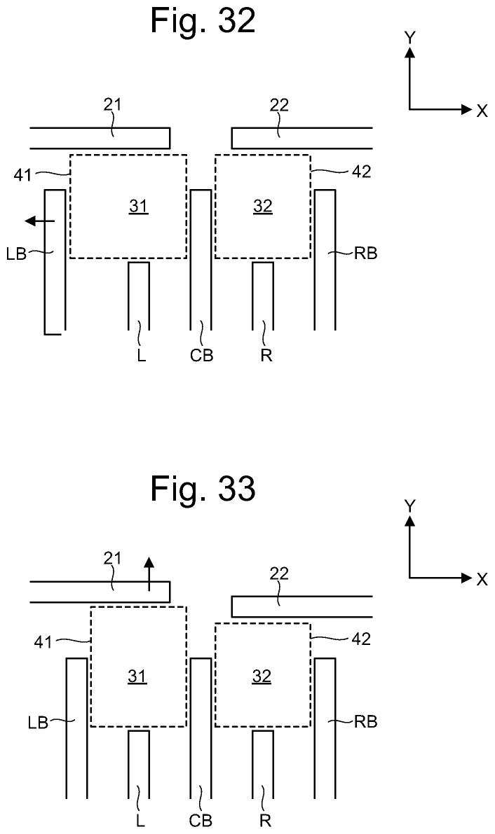

FIG. 32 depicts an example where a separation between electrodes LB and CB of the X-axis pair of the first set is increased to provide an asymmetric electrode arrangement. The asymmetric arrangement again results in the first containment region 41 being larger than the second containment region 42.

FIG. 33 depicts an example where a separation between electrodes L and 21 of the Y-axis pair of the first set is increased by moving the electrode 21 upwards (in the figure) to provide an asymmetric electrode arrangement. The asymmetric arrangement again results in the first containment region 41 being larger than the second containment region 42. The displacement of the electrode 21 also results in the cross electrode of the first set (electrode 21) and the cross electrode of the second set (electrode 22) being misaligned with respect to each other along the X-axis. In the example shown, the cross electrodes (electrodes 21 and 22) are misaligned by being at different positions along the Y-axis. Other misalignment modes are possible, such as misalignment by being angled differently relative to the X-axis (e.g., by one or both of the cross electrodes being arranged at a non-zero angle, e.g. an oblique angle, relative to the X-axis).

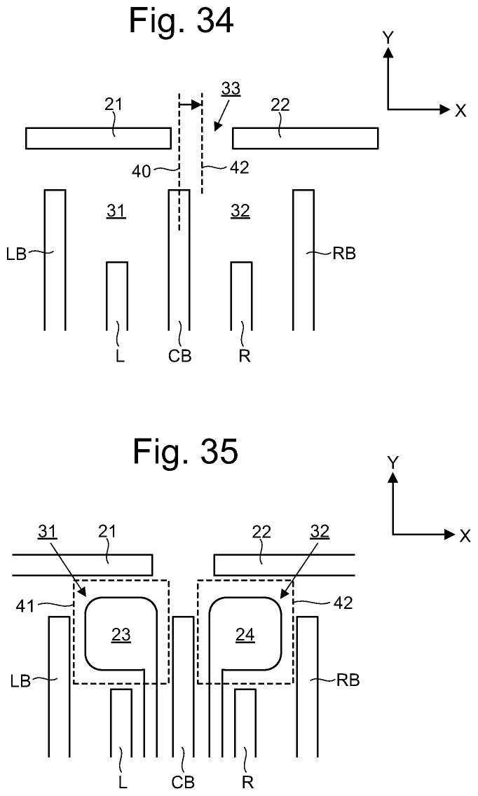

FIG. 34 depicts an example where a gap 33 between the cross electrode of the first set (electrode 21 in FIG. 34) and the cross electrode of the second set (electrode 22 in FIG. 34) in a direction parallel to the X-axis is displaced along the X-axis (see horizontal arrow pointing the right) by more than 5 nm, preferably by more than 10 nm, preferably by more than 20 nm, from a symmetric position relative to the shared intermediate electrode CB (e.g. aligned with symmetry axis 40). Thus, in the example shown an axis of mirror symmetry 40 passing vertically through the shared intermediate electrode CB does not pass through a centre 42 of the gap 33. The gap 33 is displaced to the right relative to the axis 40. The effect is to enlarge and/or change the shape of the second quantum dot relative to the first quantum dot and thereby contribute to a larger g-factor difference.

In some embodiments, a large g-factor difference is at least partially achieved by deliberately localizing wavefunctions of the first and second holes in regions having different composition. For example, a composition of the quantum well layer may be configured to vary in a depth direction (i.e. as a function of depth). This may be achieved by controlling the growth process of the quantum well layer for example. The variation in composition may be U-shaped or V-shaped or asymmetrically U- and V-shaped in the depth direction or may be made to increase or decrease monotonically, e.g. linearly, as a function of depth. The device is configured to localize the wavefunctions of the first (in the first quantum dot) and second (in the second quantum dot) holes (e.g. their centres of mass) at different depths in the quantum well layer 12 and thereby achieve the localization in regions having different composition. For example, the localization of wavefunctions may be such that a centre of mass of the wavefunction of the first hole is at a first location in the quantum well layer 12, the centre of mass of the wavefunction of the second hole is at a second location in the quantum well layer 12, and the quantum well layer 12 has different compositions at the first and second locations.

To a first approximation the out-of-plane g-factor of holes in Ge is 6 k, where k is a Luttinger parameter that depends on the composition. According to theory, it is expected that k will be about 3.41 for 100% Ge while it is about 1.153 for 80% Ge. This would imply a factor of 3 change in the g-factor (3 times smaller at 80% Ge compared to 100% Ge). Based on this insight, in some embodiments a concentration of Ge in the quantum well layer 12 is configured to vary in the depth direction by more than 10%, preferably more than 15%, preferably more than 20%, of a maximum concentration of Ge in the quantum well layer. For example, the Ge composition may be made to vary from 100% Ge to at least 90% Ge, to at least 85% Ge or to at least 80% Ge. The quantum well layer 12 may for example have the composition SiₓGe₁₋ₓ where x varies over a range of size 0.1, 0.15 or 0.2, optionally with upper and lower limits that are between 0 and 0.4. In the example given above where the centre of masses of the wavefunctions of the first and second holes were at first and second positions, the first and second positions may thus be at different depths in the quantum well layer 12 and/or the concentration of Ge may be at least 10% different, preferably at least 15% different, preferably at least 20% different, at the first location compared with the second location.

In some embodiments, as exemplified in FIG. 35, either or both of the first and second sets of electrodes comprises a depth control electrode 23, 24. Each depth control electrode 23, 24 controls localization (e.g. a position) of the wavefunction of the first hole or the second hole in a depth direction of the quantum well layer 12. In the example shown, the first set of electrodes comprises a first depth control electrode 23 for controlling localization of the wavefunction of the first hole in the depth direction and the second set of electrodes comprises a second depth control electrode 24 for controlling the position of the wavefunction of the second hole in the depth direction. Each depth control electrode 23, 24 will typically have a larger surface area parallel to the plane of the quantum well layer 12 than any of the other electrodes in the same set of electrodes. Each depth control electrode 23, 24 may be positioned substantially over the respective quantum dot. The depth control electrodes 23, 24 may be provided in the same layer as one or more (or all) of the other electrodes, or in a different layer (preferably in a layer above, i.e. further away from the quantum well layer 12 than, electrodes of other layers). In the case where the depth control electrodes are provided in a different layer, an insulating layer such as an oxide layer may be provided between the depth control electrodes and electrodes in a different layer. The oxide layer may have a thickness in the range of 5-30 nm for example. Each depth control electrode 23, 24 may have a surface area that is larger than 50%, preferably larger than 75%, preferably larger than 90%, preferably larger than 110%, preferably larger than 130%, preferably larger than 150%, of the respective containment region 41 or 42. Each depth control electrode 23, 24 may be positioned between electrodes of the X-axis pair and/or Y-axis pair of the respective set of electrodes (e.g. the depth control electrode 23 is positioned between electrodes of the X-axis and Y-axis pairs of the first set and the depth control electrode 24 is positioned between electrodes of the X-axis and Y-axis pairs of the second set). This will be particularly desirable where the depth control electrodes 23, 24 are formed in the same layer as the other electrodes. The depth control electrodes 23, 24 may be arranged to overlap the one or more electrodes of the X-axis and/or Y-axis pairs when the depth control electrodes 23, 24 are formed in a different layer.

A method of operating a qubit device according to any of the embodiments described herein may be provided. The method comprises using a plurality of electrodes to encode a unit of quantum information in a plurality of hole spins hosted in the quantum dots. A suitably programmed controller and/or power source may be used for example to control voltages applied to the electrodes. The controller may comprise any suitable combination of hardware, firmware and/or software for providing the necessary data processing/control functionality, including where appropriate user interfaces and networking capabilities etc. The method may comprise using the electrodes (e.g. via the controller and/or power source) to form a double quantum dot having a first quantum dot hosting a first hole participating in the encoding of the unit of quantum information and a second quantum dot hosting a second hole participating in the encoding of the unit of quantum information. As described above, the electrodes may be controlled such that the size, shape, orientation, hole occupancy in the first quantum dot, localization of the wavefunction of the first hole and/or electric field experienced by the first hole is/are respectively different from the size, shape, orientation, hole occupancy in the second quantum dot, localization of the wavefunction of the second hole and/or electric field experienced by the second hole.

Z-rotations on the Bloch sphere can be implemented by making use of the exchange interaction, i.e. wavefunction overlap between the quantum dots. Z-rotations may thus be switched on by allowing wavefunction overlap between the quantum dots. For example, the qubit may be initialized in one state (e.g., a singlet state). The electrodes may then be used to apply an electrical pulse that brings the qubit system close to the equator of the Bloch sphere and, subsequently, the electrodes may be used to increase the exchange interaction (by increasing wavefunction overlap, for example by lowering the tunnel barrier potential) to cause rotation about the Z axis (or about an axis near to the Z axis).

Qubits according to the present disclosure could be integrated with Ge gatemon qubits (based on Ge Josephson junctions) implemented in the same heterostructure as well as with superconducting resonators fabricated for example out of Al, Nb or granular Al and Josephson parametric amplifiers.

The qubit will typically be operated at very low temperatures. In the example described below, the qubit was measured at around 20 mK. It may be possible to measure the qubit at higher temperatures, for example in the range of 10 mK to 4K.

### EXAMPLE

An exemplary embodiment is described in further detail below. In this example, the qubit device uses Ge hole spins in a double quantum dot (DQD).

The quantum well structure 2 was provided as a strained SiGe\Ge\SiGe heterostructure grown by low-energy plasma-enhanced chemical vapor deposition (LEP-ECVD). Holes confined in a quantum well of this example are of heavy-hole (HH) type because compressive strain and confinement move light-holes (LHs) to higher energies. The related Kramers doublet of the spin S_{z}=±3/2 states therefore resembles an effective spin-1/2 system, |↑> and |↓>.

FIG. 3 is a scanning electron microscope (SEM) image of a gate layout used for implementing the control arrangement of this example. Single layer devices can be fabricated because without the application of any negative accumulation voltage a charge carrier density of 9.7×10¹¹ cm⁻² was measured. Secondary Ion Mass Spectrometry (SIMS) analysis rules out boron doping in the region of the QW as a source of this carrier density. Without wishing to be bound by theory, it is believed that the high carrier density arises due to the p-type background doping of the Si wafer on which the quantum well structure was formed or due to the existing dislocations and vacancies, in combination with fixed negative charges in the deposited gate oxide.

In a singlet-triplet qubit the logical quantum states are defined in a 2-spin ½ system with total spin along the quantization axis S_{z}=0. This can be achieved by confining one spin in each of two tunnel coupled quantum dots. In the present example, the two tunnel coupled quantum dots are formed by depletion gates as depicted in FIG. 3. The device can be tuned in the single hole transport regime, as shown by the stability diagrams in FIGS. 4 and 5, where the sensor dot reflected phase signal (ϕ_{refl}) is displayed as a function of the voltage on L and R gates shown in FIG. 3.

Each Coulomb blocked region corresponds to a fixed hole occupancy, and is labelled by (N_{L}, N_{R}), with N_{L} (N_{R}) being the number of holes in the left (right) quantum dot. Interdot and dot-lead charge transitions appear as steep changes in the sensor signal. It is possible to deplete the left quantum dot completely while still observing charge transitions at the highest possible voltage on R. Therefore, a precise determination of the hole number in the right dot is not possible.

By pulsing in a clockwise manner along the E-S-M vertices (see FIG. 5) a triangular region leaking inside the upper-left Coulomb blocked region is observed. Such feature identifies the metastable region where Pauli spin blockade (PSB) occurs: once initialized in E (‘empty’), the pulse to S loads a charge and the spins are separated forming either a spin singlet or a triplet. At the measurement point M within the marked triangle, the spin singlet state leads to tunnel events, while the triplet states remain blocked, which allows spin-to-charge conversion. If the pulsing is performed with a counter-clockwise ordering (E-M-S), no metastable region is observed, as expected (FIG. 4 was acquired while pulsing in the counter-clockwise ordering). It is thus considered that the interdot line across the detuning (ϵ) axis of FIG. 4 is equivalent to the (2,0)⇄(1,1) effective charge transitions. The system can be tuned along the detuning axis from (2,0) to (1,1) by appropriately pulsing on the LB and RB terminals shown in FIG. 3.

A DQD spectrum for a finite B field is shown in FIG. 6 (upper graph). The triplet states T(2,0) lie high up in energy and are not shown. The inventors set ϵ=0 at the (2,0)⇄(1,1) crossing. Starting from (2,0) increasing ϵ mixes (2,0) and (1,1) into two molecular singlets, the ground state S_{G}:=S and the excited state S_{E}, which is neglected in the following. The two molecular singlets are split at resonance by the tunnel coupling 2\sqrt{2}t_{C}. The triplets are almost unaffected. The exchange energy J is defined as the energy difference between

$$S = \frac{1}{\sqrt{2}} ( \vert ↑ ↓ 〉 - \vert ↓ ↑ 〉 )$$

and the unpolarized triplet

$${T}_{0} = \frac{1}{\sqrt{2}} ( \vert ↑ ↓ 〉 + \vert ↓ ↑ 〉 )$$

At deep positive detuning J drops due to the decrease of the wavefunction overlap for the two separated holes. Importantly, different g-factors for the left (g_{L}) and the right dot (g_{R}) result in four (1,1) states: two polarized triplets |T₋ [symbol] =|↓↓ [symbol] , |T₊ [symbol] =|↑↑ [symbol] and two anti-parallel spin states |↑↓ [symbol] , |↓↑ [symbol] split by ΔE_{Z}=Δgμ_{B}B, where Δg=|g_{L}−g_{R}|, μ_{B} is the Bohr magneton and B is the magnetic field applied in the out-of-plane direction. Even at large positive ϵ a residual J can be measured, which leads to the total energy splitting between |↑↓ [symbol] and |↓↑ [symbol] being Eₜₒₜ=\sqrt{J(ϵ)²+(Δgμ_{B}B)²}. A funnel experiment maps out the degeneracy between J(ϵ) and

$${E}_{Z}^{T} = \pm \frac{\sum g {μ}_{B} B}{2} ,$$

where E_{Z}^{T} is the Zeeman energy of the polarized triplets and Σg=g_{L}+g_{R}. By applying a pulse with varying ϵ (lower graph of FIG. 6) and stepping the magnetic field the plot in FIG. 7 is obtained. A doubling of the degeneracy point can be attributed to fast spin-orbit induced S−T₋ oscillations. At larger detuning S−T₀ oscillations become visible.

The effective Hamiltonian of the qubit subsystem is

$$H = ( \begin{matrix}- J ( ϵ ) & \frac{Δ g {μ}_{B} B}{2} \\ \frac{Δ g {μ}_{B} B}{2} & 0\end{matrix} ) \qquad ( 1 )$$

in the {|S [symbol] , |T [symbol] } basis, with J(ϵ) being the detuning-dependent exchange energy, common to all S−T₀ qubits. Here the S−T₀ coupling can be controlled both directly via the magnetic field and by electric fields affecting the g-factors. Pulsing on ϵ influences J and the ratio between J and Δgμ_{B}B determines the rotation axis tilted by an angle

$$θ = arctan ( \frac{Δ g {μ}_{B} B}{J ( ε )} )$$

from the Z-axis of the Bloch sphere. For large detuning θ→90°, which corresponds to X-rotations. For small detuning θ→0°, which corresponds to Z-rotations.

A demonstration of coherent X-rotations performed by the inventors is described below with reference to FIGS. 8-14.

State evolution on the Bloch sphere is depicted in FIG. 8. The dashed trajectory 31 corresponds to a perfect X-rotation while the effective rotation axis is tilted by an angle θ from the Z-axis due to a finite residual J (indicated by an arrow pointing along the Z-axis). X-rotations are controlled by Δg and magnetic field and the resulting rotation axis is indicated by arrow 32. The real trajectory and rotation axis are indicated respectively by labels 61 and 62.

In the present example, a center barrier voltage of V_{CB}=910 mV is applied with a pulse sequence as depicted in FIG. 9 (varying separation time τ_{S} with amplitude ϵ=2.8 meV). The system is first initialized in (2,0) in a singlet, then pulsed quickly deep into (1,1) where the holes are separated. Here the state evolves in a plane tilted by θ as depicted in FIG. 8. Variation of the angle θ as a function of magnetic field B, given by

$$θ = arctan \frac{J ( 2.8 meV )}{Δ g {μ}_{B} B} ,$$

is shown in FIG. 11. The effective oscillation axis is thus magnetic field dependent and approaches 80° for B=5 mT. After a separation time τ_{S} the system is brought quickly to the measurement point in (2,0) where PSB enables the distinction of triplet and singlet. Varying τ_{S} produces sinusoidal X-oscillations (observed as oscillations in Φ_{refl} as a function of τ_{S} for fixed magnetic field B) with frequency

$$f = \frac{1}{h} \sqrt{{J}^{2} + {( Δ g {μ}_{B} B )}^{2}} ,$$

as shown in FIG. 10. The average of each column has been subtracted to account for variations in the reflectometry signal caused by magnetic field. A low (high) signal corresponds to a higher singlet (triplet) probability. Each point is integrated for 100 ms under continuous pulsing. The variation of the frequency ƒ as a function of magnetic field B is depicted in FIG. 12. The black line is a fit to

$$f = \frac{1}{h} \sqrt{{J}^{2} + {( Δ g {μ}_{B} B )}^{2}} ,$$

from which a g-factor difference Δg=2.04±0.04 and a residual exchange interaction J(ϵ=2.8 meV)=21±1 MHz are extracted. Frequencies of 100 MHz are observed at fields as low as 3 mT.

FIG. 13 shows the extracted singlet probability P_{S} as a function of τ_{S} at different B-fields for V_{CB}=910 mV, extracted through averaged single shot measurements. The black solid line for each magnetic field is a fit to

$${P}_{S} = Acos ( 2 π f {τ}_{S} + ϕ ) exp ( - {( \frac{t}{{T}_{2}^{*}} )}^{2} ) + C ,$$

where T*₂ is the inhomogeneous dephasing time. P_{S} oscillates only between 0.5 and 1 as a consequence of J(ϵ=2.8 meV)≠0 and the tilted rotation axis. One would expect an increase in the oscillation amplitude with higher magnetic field. However, at large ΔE_{Z} the T₀ state quickly decays to the singlet during readout, reducing the visibility as is clearly shown by the curve at 2 mT in FIG. 13. This could be circumvented by different read-out schemes such as latching or shelving. A dependence of Δg on the voltage on CB, V_{CB}, is also observed, as shown in FIG. 14 (upper graph), confirming electrical control over the g-factors. As the voltage is decreased by 50 mV, Δg varies from ≈1.5 to more than 2.2 which conversely increases the frequency of X-rotations. Concurrently we measure a similar trend in T*₂ reported at B=1 mT in the lower graph in FIG. 14. As the center barrier is lowered the coherence of the qubit is enhanced. The origin and consequences of this observation are discussed below.

A demonstration of Z-rotations performed by the inventors is described below with reference to FIGS. 15-23.

Z-rotations are achieved by leveraging the exchange interaction and are performed at B=1 mT and V_{CB}=910 mV. State evolution on the Bloch sphere is depicted in FIG. 15. The pulse sequence used to perform Z-rotations is depicted in FIG. 16. The pulse sequence is such that after initialization in a singlet the system is pulsed to maximum detuning but is maintained in this position only for t=t_{π/2} corresponding to a πₓ/2 rotation (indicated by arrow 33 in FIG. 15), bringing the system close to i|↑↓ [symbol] (i.e. close to the equator of the Bloch sphere). Now we let the state evolve for a time τ_{S} at a smaller detuning (indicated by trajectory 34), increasing J and changing the rotation angle θ, before applying another πₓ/2 rotation (indicated by arrow 35 in FIG. 15) at high detuning and pulsing back to read-out. The state evolution on the Bloch sphere in FIG. 15 shows that full access to the qubit space can be obtained by a combination of appropriately timed pulses. The resulting oscillation pattern is depicted in FIG. 17. From the inferred frequency we find the dependence of J on ϵ and extract t_{c}/h=1.86 GHz as a free fitting parameter. J as a function of ϵ is given by

$$J = \sqrt{{f ( ϵ )}^{2} - {( \frac{Δ g {μ}_{B} B}{h} )}^{2}}$$

and can be obtained by extracting the oscillation frequency from FIG. 17. The extracted values of J are plotted in FIG. 19 with the darker markers 36 obtained from the exchange oscillation frequency. The lighter markers 37, on the other hand, correspond to

$$J ( ϵ ) = {E}_{Z}^{T} = \frac{\sum g {μ}_{B} B}{2}$$

extracted from the funnel experiment (FIG. 7). The inventors found that the two sets of data points coincide when Σg=11.0. The fit line is the best fit to

$$J ( ϵ ) = \vert \frac{ϵ}{2} - \sqrt{\frac{{ϵ}^{2}}{4} + 2 {t}_{C}^{2}} \vert .$$

Together with the g-factor difference already reported the two out-of-plane g-factors are found to be 4.5 and 6.5. In FIGS. 20 and 21, P_{S} is plotted as a function of separation time τ_{S} at different values of ϵ (with +1 offset for clarity). P_{S} now oscillates between 0 and 1 due to the combination of π/2-pulses and free evolution time at lower detuning. From the fits (black solid lines) at different detunings T*₂ as a function of ϵ is extracted (FIG. 23). For low ϵ the coherence time is very short, while it increases for larger ϵ and saturates at around 2 meV. This can be explained by a simple noise model where T*₂ depends on electric noise on J and magnetic noise affecting ΔE_{Z}:

$$\frac{1}{{T}_{2}^{*}} = \frac{π \sqrt{2}}{h} \sqrt{{( \frac{J ( ϵ )}{{E}_{tot}} \frac{d J}{d ϵ} {δϵ}_{rms} )}^{2} + {( \frac{Δ {E}_{Z}}{{E}_{tot}} δΔ {E}_{{Z}_{rms}} )}^{2}} \qquad ( 2 )$$

where δϵᵣₘₛ is the rms noise on detuning, δΔE_{Z}_{ᵣₘₛ} is the magnetic noise. It is assumed that

$$\frac{d Δ {E}_{Z}}{d ϵ} \approx 0$$

as almost no change in Δg with detuning is observed. From the fit (dark line 38) it is found that δϵᵣₘₛ=7.59±0.35 μeV, and δΔE_{Z}_{ᵣₘₛ}=1.78±0.01 neV (smaller by a factor of 2 than in a comparable natural Si qubit). Although δΔE_{Z}_{ᵣₘₛ} is much smaller than δϵᵣₘₛ it is found that coherence at large detuning is still limited by magnetic noise because

$$\frac{d J}{d ϵ} \to 0$$

(see broken lines 39 and 40 in FIG. 23). For low detuning clearly charge noise is limiting, while at large detuning magnetic noise becomes dominant. It is believed that the magnetic noise is due to randomly fluctuating hyperfine fields caused by spin-carrying isotopes in natural Ge. Eq. 2 gives also insight into the trends observed in FIGS. 13 and 14 (lower graph). With B we now affect ΔE_{Z} and, thereby, the ratio to the total energy. The higher this ratio the more the coherence is limited by magnetic noise as confirmed by the drop in T*₂ with magnetic field in FIG. 13. Similarly one would expect that by increasing Δg, T*₂ should be lower. But, as shown in FIG. 22, the raising g-factor difference is accompanied by an increase of the tunnel coupling by 2 GHz. Hence, J is larger at lower V_{CB} and ΔE_{Z}/Eₜₒₜ is reduced leading to a longer T*₂. While V_{CB} affects both t_{C} and Δg, we see that V_{LB} and V_{RB} affect mostly T_{C} and leave Δg unaltered. This exceptional tunability enables electrical engineering of the potential landscape to favor fast operations without negatively affecting the coherence times, thus enhancing the quality factor of this qubit. While the longest T*₂ reported here is already comparable to electron singlet-triplet qubits in natural Si, a reduction in the magnetic noise contribution by isotopic purification will further improve qubit coherence and quality.

It is now explained with reference to FIGS. 24-29 how the coherence of the qubit can be extended by applying refocusing pulses similar to those developed in nuclear magnetic resonance (NMR) experiments. The discussion focusses on the high ϵ region where charge noise is lowest.

FIG. 24 depicts state evolution on the Bloch sphere. The state evolves on the trajectory 50. At appropriate times, a short exchange pulse is applied (at ϵ=0.4 meV in the example shown), which causes the state to follow the trajectory 51. The exchange pulse may be referred to as a refocusing pulse. The state again evolves on the trajectory 50 after the trajectory 51. To obtain a perfect correcting pulse, it would be necessary to implement a more complex pulse scheme. In the present example, convenient τ_{S} values

$$( {τ}_{S} = ( 2 n + \frac{1}{2} ) {t}_{{π}_{x}} )$$

are chosen such that, if no decoherence has occurred, the system will always be found in the same state after τ_{S}. The refocusing pulse is then calibrated to apply a π-pulse that brings the state on the same trajectory (i.e. the trajectory 50) as before the refocusing pulse. t_{π}_{ₓ} is the time needed for a π-rotation along the trajectory 50. The free evolution time after the last refocusing pulse τ_{S′} is varied in length from τ_{S}−δt to τ_{S}+δt as depicted in FIGS. 25 and 26 (for one and two refocussing pulses respectively). FIG. 27 depicts the normalized echo amplitude as a function of total separation time for the resulting oscillations. Solid lines are a fit to A_{E} exp(−t/T₂^{Echo}) with A_{E} being the normalized echo amplitude. By increasing the number of π-pulses from 2 to 512 the coherence time increases accordingly from T₂^{Echo}(n_{π}=2)=4.5±0.7 μs to T₂^{Echo}(n_{π}=512)=158.7±6.2 μs. Increasing the number of applied pulses increases the total free evolution time of the qubit. A Carr-Purcell-Meiboom-Gill echo was performed. Furthermore, a power law dependence of T₂^{Echo} is observed as a function of the number of refocusing pulses and T₂^{Echo}≈n_{π}^{β} with β=0.56 is found. The fitted β can be used to extract the noise spectral density dominated by low frequency 1/f noise for n_{π}<32. Refocusing pulses exploiting the symmetric exchange operation could help increasing T₂^{Echo} further since they are carried out at a charge noise sweet spot.

The inventors have thus shown coherent 2-axis control of a hole singlet-triplet qubit in Ge with dephasing times of 1 μs at 0.5 mT. In most of the so far reported singlet-triplet qubits, X-oscillations were driven by magnetic field differences generated either by nuclear spins or by fabricated micromagnets. Here the inventors have taken advantage of an intrinsic property of heavy hole states in Ge, namely their large and electrically tunable g-factors. They have shown electrically driven X-rotation frequencies approaching 150 MHz at fields of 5 mT, which are larger than most of the reported hole spin qubit Rabi frequencies. A T*₂ was observed that exceeds those found in GaAs S−T₀ qubits, owing to a lower magnetic noise contribution, while being comparable to values reported for natural Si. This indicates that, although holes in Ge are to first order insensitive to hyperfine interaction, the spin-carrying isotopes might still limit the coherence of the qubit. Most strikingly, by tuning V_{CB} it was found possible to increase the X-rotation frequency by a factor of 1.5 while nearly doubling the inhomogeneous dephasing time of the qubit. Without wishing to be bound by theory, it is believed this observation arises due to electric tunability of the hole g-factors in combination with optimized ratios of electric and magnetic noise contributions. Latched or shelved read-out could circumvent the decay of T₀ to S during read-out opening the exploration of the qubit's behavior at slightly higher magnetic fields where the X-rotation frequencies could surpass the highest electron-dipole spin-resonance (EDSR) Rabi frequencies reported so far, without suffering from reduced dephasing times. Furthermore, by moving towards symmetric operation or resonant driving the quality of exchange oscillations can be increased since the qubit is operated at an optimal working point. The long coherence times combined with fast and simple operations at extremely low magnetic fields make this qubit an optimal candidate for integration into a large scale quantum processor.

The samples were processed in the IST Austria Nanofabrication Facility. A 6×6 mm² chip was cut out from a 4 inch wafer and cleaned before further processing. The Ohmic contacts were first patterned in a 100 keV electron beam lithography system, then a few nm of native oxide and the SiGe spacer were milled down by argon bombardment and subsequently a layer of 60 nm Pt was deposited in situ under an angle of 5°, to obtain reproducible contacts. No additional intentional annealing was performed. A mesa of 90 nm was etched in a reactive ion etching step. The native SiO₂ was removed by a 10 s dip in buffered HF before the gate oxide was deposited. The oxide is a 20 nm ALD grown aluminium oxide (Al₂O₃) grown at 300° C., which unintentionally anneals the Ohmic contacts resulting in a low resistance contact to the carriers in the quantum well. The top gates were first patterned via e-beam lithography and then a Ti/Pd 3/27 nm layer was deposited in an electron beam evaporator. The thinnest gates are 30 nm wide and 30 nm apart. An additional thick gate metal layer was subsequently written and deposited and served to overcome the Mesa step and allow wire bonding of the sample without shorting gates together. Quantum dots were formed by means of depletion gates (as shown in FIG. 3). The lower gates (LB, L, CB, R, RB) form a double quantum dot (DQD) system and the upper gates tune a charge sensor (CS) dot. The separation gates in the middle are tuned to maximize the CS sensitivity to charge transitions in the DQD. An LC-circuit connected to a CS ohmic contact allows fast read-out through microwave reflectometry. LB and RB are further connected to fast gate lines enabling fast control of the energy levels in the DQD.

Some arrangements of the disclosure are defined in the following numbered clauses.
1. A qubit device, comprising:
a quantum well structure configured to host a hole gas in a quantum well; and
a plurality of electrodes configured to allow the formation of a plurality of quantum dots in the hole gas and to allow encoding of a unit of quantum information in a plurality of hole spins hosted in the quantum dots.
2. The device of clause 1, wherein the unit of quantum information is encoded into singlet and triplet states of the hole spins hosted in the quantum dots.
3. The device of clause 1 or 2, wherein the plurality of quantum dots consists of a double quantum dot.
4. The device of any preceding clause, wherein the hole gas is a two-dimensional hole gas.
5. The device of clause 4, wherein the quantum well structure comprises a quantum well formed within a heterostructure of semiconductor layers.
6. The device of clause 4 or 5, wherein the quantum well is formed in a quantum well layer sandwiched between two confinement layers.
7. The device of clause 6, wherein the quantum well layer is a layer comprising more than 90% Ge.
8. The device of clause 7, wherein the Ge in the quantum well layer comprises isotopically purified Ge.
9. The device of any of clauses 6-8, wherein the thickness of the quantum well layer is in the range of 1-50 nm.
10. The device of any of clauses 6-9, wherein either or both of the confinement layers comprises SiGe with a Si content in the range of 5-50% and a Ge content in the range of 95-50%.
11. The device of any of clauses 6-9, wherein either or both of the confinement layers comprises an oxide layer.
12. The device of any of clauses 6-11, wherein each of either or both of the confinement layers has a thickness in the range of 10-200 nm.
13. The device of any of clauses 6-12, wherein the electrodes are formed on an oxide layer, the oxide layer being provided above an uppermost one of the confinement layers or forming the uppermost one of the confinement layers, wherein the oxide layer preferably has a thickness in the range of 5-50 nm, further preferably comprising one or more of the following atomic layer deposition formed oxides: aluminium oxide, hafnium oxide, zirconium oxide.
14. The device of any preceding clause, configured to: implement X-rotations on the Bloch sphere of the qubit using a g-factor difference between hole spins and an applied magnetic field, wherein the applied magnetic field is preferably below 100 mT; and/or to implement Z-rotations on the Bloch sphere of the qubit using the exchange interaction.
15. A method of operating a qubit device, comprising:
providing the qubit device of any preceding clause; and
using the plurality of electrodes to encode a unit of quantum information in a plurality of hole spins hosted in the quantum dots.
16. A method of operating a qubit device, comprising:
providing a quantum well structure that hosts a hole gas in a quantum well;
using a plurality of electrodes to form a plurality of quantum dots in the hole gas; and
using the electrodes to encode a unit of quantum information in a plurality of hole spins hosted in the quantum dots.
17. The method of clause 16, wherein the unit of quantum information is encoded into singlet and triplet states of the hole spins hosted in the quantum dots.
18. The method of clause 16 or 17, wherein the plurality of quantum dots consists of a double quantum dot.
19. The method of any of clauses 16-18, wherein the hole gas is a two-dimensional hole gas.
20. The method of clause 19, wherein the quantum well structure comprises a quantum well formed within a heterostructure of semiconductor layers.
21. The method of clause 19 or 20, wherein the quantum well is formed in a quantum well layer sandwiched between two confinement layers.
22. The method of clause 21, wherein the quantum well layer is a layer comprising more than 90% Ge.
23. The method of clause 22, wherein the Ge in the quantum well layer comprises isotopically purified Ge.
24. The method of any of clauses 21-23, wherein a thickness of the quantum well layer is in the range of 1-50 nm.
25. The method of any of clauses 21-24, wherein either or both of the confinement layers comprises SiGe with a Si content in the range of 5-50% and a Ge content in the range of 95-50%.
26. The method of any of clauses 21-25, wherein either or both of the confinement layers comprises an oxide layer.
27. The method of any of clauses 21-26, wherein each of either or both of the confinement layers has a thickness in the range of 10-200 nm.
28. The method of any of clauses 21-27, wherein the electrodes are formed on an oxide layer, the oxide layer being provided above an uppermost one of the confinement layers or forming the uppermost one of the confinement layers, wherein the oxide layer preferably has a thickness in the range of 5-50 nm, further preferably comprising one or more of the following atomic layer deposition formed oxides: aluminium oxide, hafnium oxide, zirconium oxide.
29. The method of any of clauses 16-28, wherein the encoding of the unit of quantum information includes implementing X-rotations on the Bloch sphere of the qubit using a g-factor difference between hole spins and an applied magnetic field, wherein the applied magnetic field is preferably below 100 mT.
30. The method of any of clauses 16-29, wherein the encoding of the unit of quantum information includes implementing Z-rotations on the Bloch sphere of the qubit using the exchange interaction.

1. A qubit device, comprising:
a quantum well structure configured to host a hole gas in a quantum well; and
a plurality of electrodes configured to allow the formation of a plurality of quantum dots in the hole gas and to allow encoding of a unit of quantum information in a plurality of hole spins hosted in the quantum dots.

2. The device of claim 1, wherein the unit of quantum information is encoded into singlet and triplet states of the hole spins hosted in the quantum dots.

3. The device of claim 1, wherein the encoding of the unit of quantum information includes implementing X-rotations on the Bloch sphere of the qubit using a g-factor difference between hole spins and an applied magnetic field.

4. The device of claim 3, wherein the applied magnetic field is below 100 mT.

5. The device of claim 1, wherein:
the hole gas is a two-dimensional hole gas in a planar quantum well layer of a heterostructure of semiconductor layers;
the plurality of quantum dots comprises a double quantum dot having a first quantum dot hosting a first hole participating in the encoding of the unit of quantum information and a second quantum dot hosting a second hole participating in the encoding of the unit of quantum information; and
the plurality of electrodes comprises a first set of electrodes configured to form the first quantum dot and a second set of electrodes configured to form the second quantum dot.

6. The device of claim 5, configured to localize the wavefunctions of the first and second holes in regions having different compositions.

7. The device of claim 6, wherein a composition of the quantum well layer varies in a depth direction and the device is configured to localize the wavefunctions of the first and second holes at different depths in the quantum well layer.

8. The device of claim 7, wherein the quantum well layer has the composition SiₓGe₁₋ₓ and a concentration of Ge in the quantum well layer varies in the depth direction by more than 10% of a maximum concentration of Ge in the quantum well layer.

9. The device of claim 7, wherein either or both of the first set of electrodes and the second set of electrodes comprises a depth control electrode configured to respectively control localization in the depth direction of the wavefunction of the first hole and/or of the second hole and/or to respectively control an electric field experienced by the wavefunction of the first hole and/or of the second hole.

10. The device of claim 5, wherein the first and second sets of electrodes are arranged asymmetrically relative to each other to promote the size, shape, orientation and/or hole occupancy of the first quantum dot being different from the size, shape, orientation and/or hole occupancy of the second quantum dot.

11. The device of claim 10, wherein the asymmetric arrangement is such that the first quantum dot has a different shape to the second quantum dot when viewed perpendicularly to the plane of the quantum well layer.

12. The device of claim 11, wherein the different shape comprises a different aspect ratio.

13. The device of claim 10, wherein the asymmetric arrangement is such that the first and second quantum dots have shapes that are each defined by a respective long axis and short axis when viewed perpendicularly to the plane of the quantum well layer, preferably wherein the shapes are ellipses.

14. The device of claim 13, wherein the long axes are non-parallel to each other, preferably perpendicular to each other.

15. The device of claim 10, wherein the asymmetric arrangement is such that a maximum area of the first quantum dot viewed perpendicularly to the plane of the quantum well layer is at least 120% of a maximum area of the second quantum dot viewed perpendicularly to the plane of the quantum well layer.

16. The device of claim 10, wherein:
dimensions of the first quantum dot along orthogonal X- and Y-axes in the plane of the quantum well layer are respectively defined by an X-axis pair of electrodes of the first set and a Y-axis pair of electrodes of the first set; and
dimensions of the second quantum dot along orthogonal X- and Y-axes in the plane of the quantum well layer are respectively defined by an X-axis pair of electrodes of the second set and a Y-axis pair of electrodes of the second set.

17. The device of claim 16, wherein:
a first containment region is defined as the largest rectangular region between the X-axis and Y-axis pairs of electrodes of the first set of electrodes;
a second containment region is defined as the largest rectangular region between the X-axis and Y-axis pairs of electrodes of the second set of electrodes; and
the first containment region is at least 120% as large as the second containment region.

18. The device of claim 16, wherein the X-axis pair of the first set and the X-axis pair of the second set together comprise three electrodes extending parallel to the Y-axis, the three electrodes comprising an outer electrode of the first set, an outer electrode of the second set, and an intermediate electrode between the outer electrodes and shared between the two sets.

19. The device of claim 18, wherein:
the Y-axis pair of the first set comprises an electrode extending parallel to the Y-axis and positioned between the outer electrode of the first set and the shared intermediate electrode, and a cross electrode extending parallel to the X-axis; and
the Y-axis pair of the second set comprises an electrode extending parallel to the Y-axis and positioned between the outer electrode of the second set and the shared intermediate electrode, and a cross electrode extending parallel to the X-axis.

20. The device of claim 19, wherein the cross electrode of the first set and the cross electrode of the second set are misaligned with respective to each other along the X-axis, preferably by being at different positions along the Y-axis and/or angled differently relative to the X-axis.

21. The device of claim 19, wherein:
the cross electrode of the first set and the cross electrode of the second set are spaced apart from each other parallel to the X-axis by a gap; and
the gap is displaced along the X-axis by more than 5 nm from a symmetric position relative to the shared intermediate electrode.

22. The device of claim 16, wherein:
the first set of electrodes comprises a depth control electrode configured to control localization of the wavefunction of the first hole in a depth direction of the quantum well layer perpendicular to the plane of the quantum well layer, the depth control electrode being positioned between the electrodes of the X-axis pair and/or Y-axis pair of the first set when viewed perpendicularly to the plane of the quantum well layer and/or in a different layer to the electrodes of the X-axis pair and/or Y-axis pair of the first set; and/or
the second set of electrodes comprises a depth control electrode configured to control localization of the wavefunction of the second hole in a depth direction of the quantum well layer perpendicular to the plane of the quantum well layer, the depth control electrode being positioned between the electrodes of the X-axis pair and/or Y-axis pair of the second set when viewed perpendicularly to the plane of the quantum well layer and/or in a different layer to the electrodes of the X-axis pair and/or Y-axis pair of the second set.

23. The device of claim 5, wherein the quantum well layer is sandwiched between two confinement layers.

24. The device of claim 1, configured to implement Z-rotations on the Bloch sphere of the qubit using the exchange interaction.

25. A method of operating a qubit device, comprising:
providing the qubit device of claim 1; and
using the plurality of electrodes to encode a unit of quantum information in a plurality of hole spins hosted in the quantum dots.

26. The method of claim 25, wherein the plurality of quantum dots comprises a double quantum dot having a first quantum dot hosting a first hole participating in the encoding of the unit of quantum information and a second quantum dot hosting a second hole participating in the encoding of the unit of quantum information.

27. The method of claim 26, wherein the electrodes are controlled such that the size, shape, orientation, hole occupancy in the first quantum dot, localization of the wavefunction of the first hole and/or electric field experienced by the first hole is/are respectively different from the size, shape, orientation, hole occupancy in the second quantum dot, localization of the wavefunction of the second hole and/or electric field experienced by the second hole.

28. The method of claim 26, comprising tuning a g-factor difference, preferably to be a least 1, by adjusting at least one of the following:
a difference in size of the first quantum dot relative to the second quantum dot;
a difference in shape of the first quantum dot relative to the second quantum dot;
a difference in orientation of a shape of the first quantum dot relative to the second quantum dot;
a difference in hole occupancy in the first quantum dot compared to the second quantum dot;
a difference in composition at a location of the centre of mass of the wavefunction of the first hole compared to the second hole; and
a difference in electric field experienced by the first hole compared to the second hole.

29. The method of claim 26, wherein the electrodes are controlled such that the hole occupancy in the first quantum dot is at least 4 holes different than the hole occupancy in the second quantum dot.

30. The method of claim 28, wherein the electrodes are controlled to:
localize the wavefunctions of the first and second holes in a quantum well layer having a variation of composition as a function of position in the quantum well layer; and
provides a difference in hole occupancy in the first quantum dot compared to the second quantum dot, the difference in hole occupancy being such that wavefunctions of the first and second holes sample different average compositions in the quantum well layer.

31. The method of claim 26, wherein:
the electrodes are controlled to localize the wavefunctions of the first and second holes in a quantum well layer having a variation of composition as a function of position in the quantum well layer; and
the localization of wavefunctions is such that a centre of mass of the wavefunction of the first hole is at a first location in the quantum well layer, the centre of mass of the wavefunction of the second hole is at a second location in the quantum well layer, and the quantum well layer has different compositions at the first and second locations.

32. The method of claim 31, wherein the first and second locations are at different depths in the quantum well layer.

33. The method of claim 31, wherein the quantum well layer has the composition SiₓGe₁₋ₓ and a concentration of Ge in the quantum well layer is at least 10% different at the first location compared to the second location.
